(19) United States
(12) Patent Application Publication
(10) Pub. No.: US 2012/0001650 A1
(43) Pub. Date: Jan. 5, 2012

(54) Test Probe

(75) Inventor: Simon Jonathan Stacey, Cambridgeshire (GB)

(73) Assignee: CAMBRIDGE SILICON RADIO LIMITED, Cambridge (GB)

(21) Appl. No.: 12/974,423

(22) Filed: Dec. 21, 2010

(30) Foreign Application Priority Data
Jan. 11, 2010 (GB) 1000344.0

(51) Int. Cl. G01R 1/067; B08B 7/00

(52) U.S. Cl. 324/755.05; 324/755.01; 134/33

(57) ABSTRACT

A test probe is configured to provide conductive contact with a surface on application of the probe to the surface. The probe includes a probe body having a proximal and distal end, a probe tip located at the distal end of the probe body, the probe being configured such that, when the probe tip is applied to the surface, the probe tip is moved to rotate about its axis, whereby the shaft tip can rotatably remove oxidation and/or contamination debris from between the shaft tip and the surface.

### FIELD OF THE INVENTION

The present invention relates to the field of test probes used to perform silicon wafer integrated circuit probe testing.

More specifically, an aspect of the invention relates to an improvement for maintaining efficient electrical contact between a probe and a contact point on the wafer.

### BACKGROUND OF THE INVENTION

During the manufacturing process of an integrated circuit residing on a silicon wafer, it is important to test the integrated circuit for the correct expected electrical continuity. This is performed using a ‘probe card’. A probe card comprises a printed circuit board (PCB) containing test circuitry and a number of probes, used to make contact with termination areas of the silicon wafer IC. As the probe card is pressed against the silicon wafer IC, contact between the probe card and the silicon wafer IC is made via the probes, and the testing of the silicon wafer IC can begin.

A well understood problem in the field of probe testing is that the termination areas on the IC can become oxidised or become contaminated with chemical residue or debris. Oxidation occurs where the metal used for the termination surface has reacted with oxygen in the air to form a layer of oxidised metal on the surface of the termination surface. Chemical residue or debris can end up covering the termination surface as a consequence of the manufacturing or packaging processes and where the cleaning process has failed to adequately clean the termination surfaces. This oxidation or contamination can form an insulating layer covering the termination surface and reduce the quality of the contact between the probe and the termination area on the silicon wafer IC. This causes poor electrical continuity between the testing card and the silicon wafer IC and can alter the testing results for the silicon wafer IC, resulting in false reporting of errors.

In order to reduce the contact resistance and to reduce the incidence of false error reporting, it becomes necessary to break through the surface oxide or contamination to expose the underlying metallization.

An attempt to address this problem has been previously made using a cantilever probe design. A cantilever probe is configured to move laterally with respect to the surface of the termination area upon contact in order to “scrub” the surface. This type of probe is only suitable for single row probes and as such, does not solve the oxidation or contamination problem when probing array termination areas which require the use of a vertical or membrane probes.

There is therefore a need for a method of reducing the contact resistance between the probe tip and an IC contact by removing the surface oxidation or contamination during probe testing.

### SUMMARY OF THE INVENTION

According to a first aspect of the invention, there is provided a probe configured to provide conductive contact with a surface on application of the probe to the surface, the probe comprising; a probe body having a proximal and distal end, a probe tip located at the distal end of the probe body, the probe being configured such that, when the probe tip is applied to the surface, the probe tip is moved to rotate about its axis, whereby the shaft tip can rotatably remove oxidation and/or contamination from between the shaft tip and the surface.

According to a second aspect of the invention, there is provided a method of removing oxidation and/or contamination from between a tip of a probe and a surface, comprising: applying the tip of the probe to the surface, rotating the tip of the probe about its axis, wherein the shaft tip is configured to rotatably remove oxidation and/or contamination from between the shaft tip and the surface.

### BRIEF DESCRIPTION OF THE DRAWINGS

Aspects of the present invention will now be described by way of example with reference to the accompanying drawings. In the drawings:

FIG. 1 shows a vertical probe comprising a compression spring;

FIG. 2 shows the probe of FIG. 1 wherein the spring has been compressed and the probe and probe tip has rotated;

FIG. 3 shows the housing of the vertical probe keyed to the helical thread on the probe shaft;

FIG. 4 shows the probe of FIG. 3 wherein the spring has been compressed and the probe housing and probe tip has rotated;

FIG. 5 shows the helical edge of the probe housing keyed to the central shaft; and

FIG. 6 shows the probe of FIG. 5 wherein the spring has been compressed and the probe housing and probe tip has rotated.

### DETAILED DESCRIPTION OF THE INVENTION

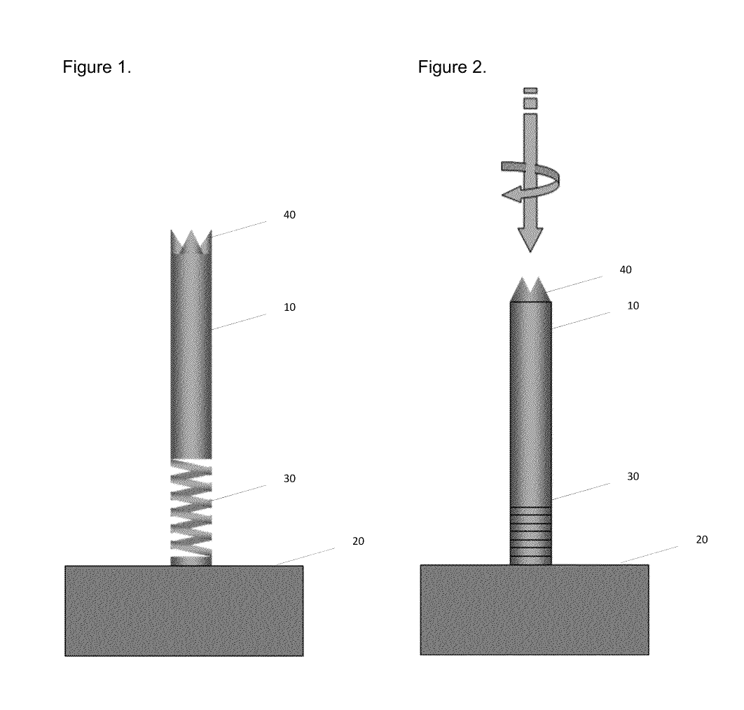

A first aspect of the invention, shown in FIG. 1, comprises a probe shaft 10 attached to probe card 20 by means of a helical compression spring 30. Probe tip 40 is fixed to the end of probe shaft 10 and comprises a surface suitable for rotatably scrubbing the surface of the termination area. The probe is compressible relative to the probe card 20, the spring providing a resistive force against compression.

The proximal end of compression spring 30 is fixed to probe card 20. As the spring is compressed, the properties of the spring are such that distal end of the spring rotates around the axis of the helical spring, relative to the proximal end of the spring. As the probe shaft 10 is fixed to the distal end of the spring, it is moved to rotate as the spring is compressed. The pitch and compression length of the spring will determine the amount of radial displacement for a given lateral displacement. Once this has been established the stiffness of the spring can be adjusted by the gauge and material of the spring wire.

FIG. 2 shows the probe of FIG. 1 when tip 40 of the probe is pressed against the termination area on the wafer IC (not shown). As probe shaft 10 is pressed back against probe card 20 by the termination area, helical spring 30 is compressed and it rotates probe shaft 10 and probe tip 40. The probe card is held rotationally fast relative to the silicon wafer IC. As the probe tip rotates relative to the termination surface whilst is in contact with the termination surface, it scrubs the surface of the termination area pressing against it, cleaning it and removing the oxide and/or contamination. This improves electrical continuity between the probe and the termination area.

In other words, when the probe is applied to a termination surface, the tip of the probe comes into contact with the termination surface and electrical continuity may be established. As the probe is pressed down onto the termination surface, the probe shaft moves back against the spring and the spring is compressed. As the spring is compressed, it rotates the shaft about the shaft's axis, such that the tip of the shaft rotates against the termination surface. The tip of the shaft is such that the rotation of the tip against the termination surface removes oxide and/or contamination from between the tip and the termination surface, providing a cleaner contact between the tip and the termination surface and improving electrical continuity between the probe and the termination surface. To this end, the tip of the probe may be roughened, or may have teeth, barbs or other protrusions effective for removing oxide and/or contamination.

Whereas the first aspect relied on the helical spring to provide the rotational movement as it is compressed, other methods of inducing rotation of the probe tip may be used. For example, a helical structure used to convert between linear movement of the probe in rotational movement, such as a screw thread, may be used. In the case of a screw thread, the pitch of the screw thread must be chosen such that it is not so fine that the friction of the thread prevents linear movement being converted into rotational movement. However, the pitch must be sufficiently fine to allow, over the linear distance moved by the probe when compressed, the probe tip to rotate sufficiently to clear the debris. Other helical structures used to convert between linear movement of the probe in rotational movement may be used. For example, a helical cut on the probe shaft coupled with a notch on a structure supporting the probe shaft would force the shaft to rotate as it moved linearly relative to the supporting structure. Alternatively, a helical rail on the surface of the shaft matched to a corresponding cut on a support structure would provide a similar effect. Other configurations of helical structures are envisaged, including multiple helical threads.

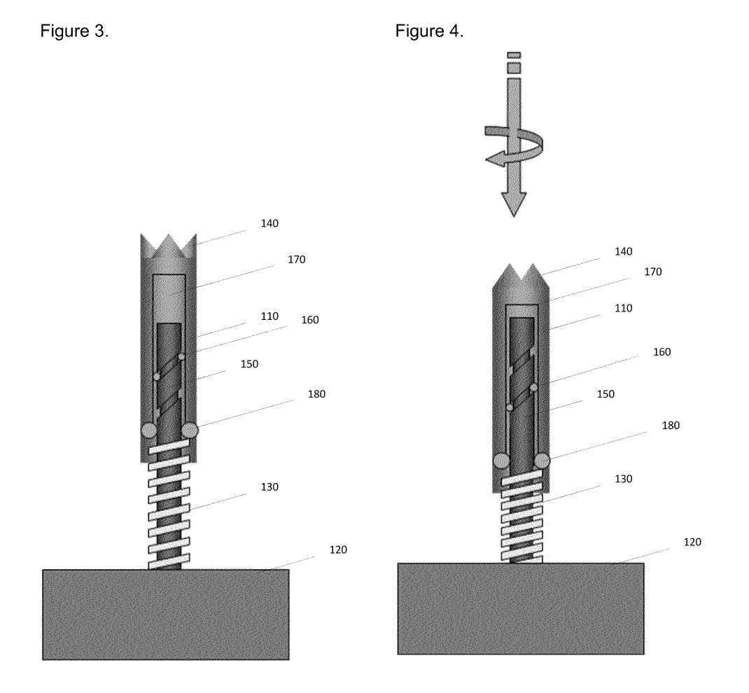

A second aspect of the invention is shown in FIG. 3. Probe housing 110 is attached to probe card 120 by means of a compression spring 130 and shaft 150. Probe housing 110 comprises probe tip 140 and an open cavity 170 in which lies shaft 150. Shaft 150 is fixed to probe card 120 and has a helical cut running along part of its length. The helical cut is keyed to a corresponding helical rail 160 on the inside of open cavity 170. The helical cut and rail are such that, when the probe housing is pressed down onto shaft 150, it is moved to rotate as it slides along the length of the shaft. This is shown in FIG. 4. As the probe housing, of which the probe tip is a part of, probe tip 140 is moved to scrub the surface in the same way as in the first aspect of the invention. An advantage of the second aspect is that the designer of the probe is able to adjust the amount of rotation per compression length more precisely by modifying the pitch of the helical cut and rail.

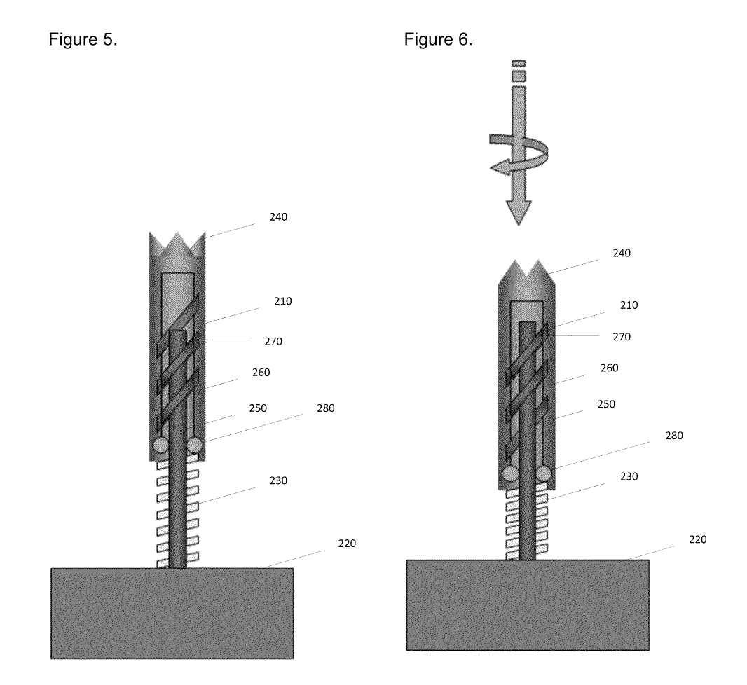

A third aspect of the invention, shown in FIG. 5, uses a similar configuration to the second aspect. However, the helical cut and rail of the cylinder and shaft are interchanged. FIG. 6 shows spring 230 compressed and probe 210 rotated, with respect to FIG. 5. The cut 270 resides on the inside surface of the cavity of the probe. The rail 260 resides on the surface of shaft 250 and is keyed to cut 270. As with the second aspect, the helical cut and rail are such that when the probe housing is pressed down onto shaft 150, it rotates as it slides along the length of the shaft. The resultant scrubbing of the termination area is the same.

Another aspect of the invention may include a probe comprising a shaft housing fixed to the probe card, the shaft housing having an internal cavity. A probe shaft is configured to reside at least partially within the internal cavity, connected by means of a helical thread to the inside surface of the shaft housing. A spring resides in the cavity and is configured to provide a resistive force on the shaft, biasing it to move out of the cavity. At the end of the shaft not residing in the cavity is the probe tip. The probe tip is configured such that the rotation of the tip against a surface against which it is applied removes oxidation and/or contamination from between the tip and the surface. When the tip is applied to a surface and the probe is pressed down onto the surface, the shaft is forced back down into the cavity and is rotated by means of the helical thread. This rotates the tip of the shaft against the surface and removes the oxidation and/or contamination from between the tip and the surface. When the probe is no longer applied to the surface, the spring biases the shaft partially back out of the cavity and the shaft rotates back into its rotational starting position.

In another aspect of the invention, the tip of the probe can be rotated about its axis by means of an electrical motor or other suitable driving means. As the probe is compressed, the motor is controlled to rotate the probe tip for a period of time, causing the probe tip to rotate against the termination surface so as to remove debris from between the tip and the surface. This embodiment may include a sensory arrangement to detect application of the probe to a surface, including electrical detection of electrical continuity or compression of the probe.

The spring may be made out of steel or other suitable metals. Alternatively, the spring may be made out of rubber or plastic. The spring may be located externally to the shaft of the probe and may be connected to the shaft via a flange. This would allow the spring to be easily replaced. The spring may form a conventional spiral or, in all but the first aspect, it might be in a leaf spring configuration with either lateral or longitudinal compression. Other embodiments of the spring may include a pneumatic or hydraulic arrangement, such that the resistive force is provided by compressed air or fluid when the probe is compressed. An alternative embodiment, in all but the first aspect, may use two magnets with like poles facing each other, one in the base of the probe housing and one at the base of the probe shaft. The facing like poles would repel each other and provide the resistive force required at the probe tip.

Aspects of the probe may be used individually, as part of a row of probes, and as part of an array of probes for probing array termination areas. The probe may be suitable for probing onto wafers, singulated dies, printed circuit boards (PCBs), and contact pads as well as for other uses. The probes may be used for making an electrical measurement or delivering an electrical stimulus.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. A probe configured to provide conductive contact with a surface on application of the probe to the surface, the probe comprising;
a probe body having a proximal and distal end,
a probe tip located at the distal end of the probe body,
the probe being configured such that, when the probe tip is applied to the surface, the probe tip is moved to rotate about its axis, whereby the shaft tip can rotatably remove oxidation and/or contamination from between the shaft tip and the surface.

2. The probe of claim 1, wherein the probe is compressible and compression of the probe through application of the probe tip to the surface causes the probe tip to rotate.

3. The probe of claim 2, further comprising a helical spring configured to provide a resistive force against compression of the probe.

4. The probe of claim 3, wherein, on compression of the spring, the spring is configured to move the probe tip to rotate about its axis.

5. The probe of claim 2, the probe body comprising:
a proximal component configured to remain rotationally fast relative to the surface,
a distal component slidably connected to the proximal component and configured to rotate relative to the surface as it slides relative to the proximal component, the probe tip being fixed to the distal component.

6. The probe of claim 5, wherein, the proximal and distal components are connected by means of a helical interconnect.

7. The probe of claim 6, wherein the helical interconnect is a screw thread.

8. The probe of claim 6, wherein the helical interconnect is a helical cut in the proximal component and a corresponding helical rail on the distal component.

9. The probe of claim 1, wherein, on application of the probe tip to the surface, the probe tip is driven to rotate by means of a rotation actuator.

10. The probe of claim 9, wherein the rotation actuator is an electric motor.

11. The probe of claim 1, wherein the probe is suitable for testing integrated circuits and the proximal end of the probe is fixed to a test probe card.

12. A method of removing oxidation and/or contamination from between a tip of a probe and a surface, comprising:
applying the tip of the probe to the surface,
rotating the tip of the probe about its axis,
wherein the shaft tip is configured to rotatably remove oxidation and/or contamination from between the shaft tip and the surface.
